(19) United States
(12) Patent Application Publication
(10) Pub. No.: US 2012/0194991 A1
(43) Pub. Date: Aug. 2, 2012

(54) EXPANSION CARD AND COMPUTER SYSTEM WITH EXPANSION CARD

(75) Inventors: XIANG ZHANG, Wuhan City (CN); CHAO GENG, Wuhan City (CN); BIAO ZENG, Wuhan City (CN); ZHI-GUO ZHANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/326,405

(22) Filed: Dec. 15, 2011

(30) Foreign Application Priority Data
Jan. 27, 2011 (CN) 201110029627.6

(51) Int. Cl. H05K 7/10; H05K 1/18

(52) U.S. Cl. 361/679.32; 361/748

(57) ABSTRACT

An expansion card and a computer system with the expansion card are disclosed. The expansion card includes a card body, and a mounting member includes a base and a support extending from the base. The base is fixed to the card body and defines a first plane facing the card body. The support defines an edge substantially extending from the base. An angle defined between the edge and the first plane is not less than about 30 degrees, but not more than about 60 degrees.

### BACKGROUND

1. Technical Field

The present disclosure relates to an expansion card and a computer system with the expansion card.

2. Description of Related Art

Many expansion cards are provided in a computer system for improving the capabilities. An expansion card includes a card body and a mounting plate. The card body defines a plurality of card holes. The mounting plate includes a base and a plurality of mounting pieces extending from the base. Each mounting piece defines a mounting hole. A plurality of screws is fixed into the mounting holes of the plurality of mounting pieces and the plurality of card holes, to secure the mounting plate to the card body. When the expansion card is secured to a chassis of the computer system, the card body is inserted in a socket of a motherboard, which is received in the chassis, and the mounting plate is secured to the chassis. Conventionally, each mounting piece includes two edges extending from the base, and the two edges are perpendicular to the base. When the computer system is in use, vibration from the computer system may be transmitted to the card body and cause the mounting pieces vibrating relative to the base, which, in turn, may damage the connections between the mounting pieces and the base.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a computer system in accordance with an embodiment.

FIG. 2 is an enlarged view of a circled portion II of FIG. 1.

FIG. 3 is an isometric view of a mounting member of the computer system of FIG. 1.

FIG. 4 is an assembled view of the computer system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

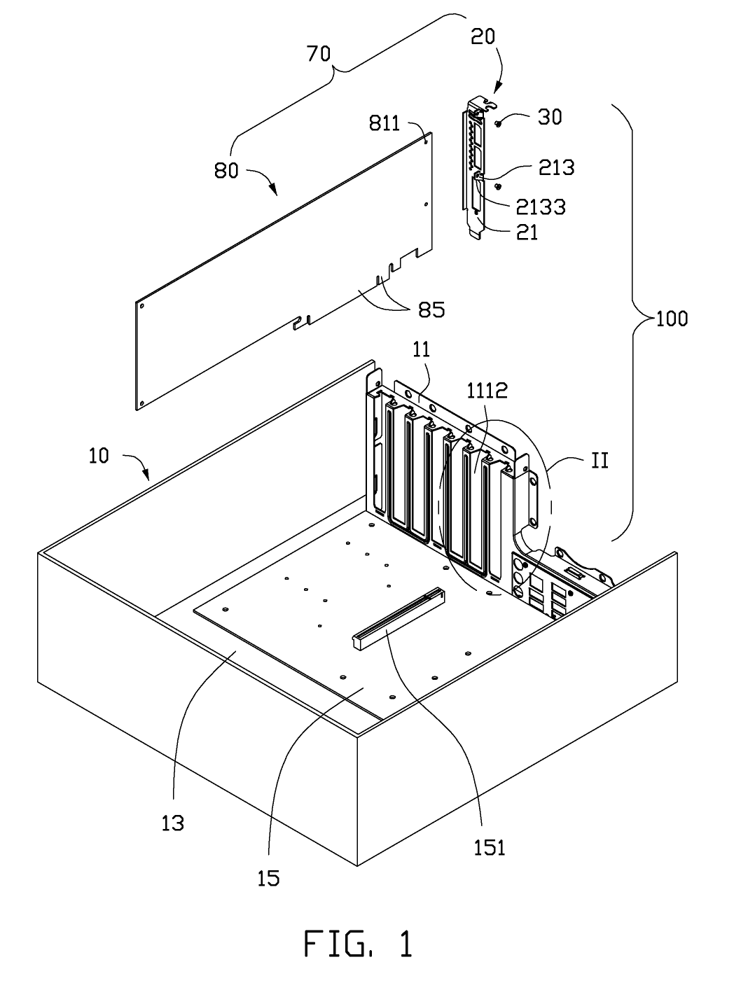

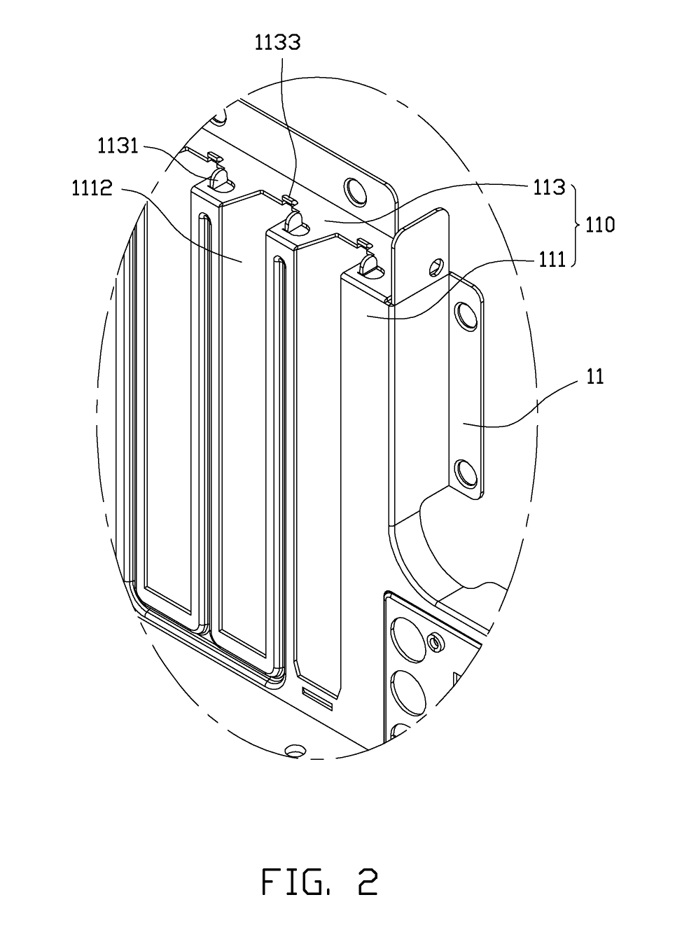

Referring to FIGS. 1-2, a computer system 100 in accordance with an embodiment comprises a chassis 10, a motherboard 15 and an expansion card 70. The expansion card 70 may be, for example, a sound card, a video card, a graphics card, etc., for enhancing the capabilities of the computer system 100.

The chassis 10 comprises a bottom plate 13 and a side plate 11 located on the bottom plate 13. The side plate 11 comprises a card cage 110. The card cage 110 comprises a retaining portion 113 and a positioning portion 111. A plurality of openings 1112 are defined in positioning portion 111 and extends into the retaining portion 113. A first tab 1131 and a second tab 1133 are located on the retaining portion 113 on two sides of each of the plurality of openings 1112. In an embodiment, the side plate 11 is substantially perpendicular to the bottom plate 13. The motherboard 15 is secured to the bottom plate 13 and comprises a socket 151.

The expansion card 70 comprises a card body 80 and a mounting member 20 attached to the card body 80. The card body 80 comprises an inserting portion 85 configured to be engaged in the socket 151, for electronically coupling the card body 80 to the motherboard 15. Two mounting holes 811 are defined in the card body 80. The inserting portion 85 and the two mounting holes 811 are located on two adjacent sides of the card body 80.

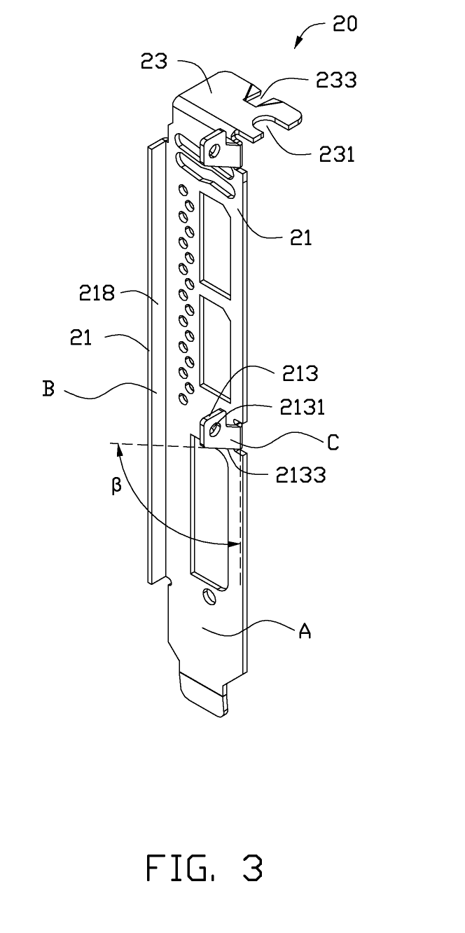

Referring to FIG. 3, the mounting member 20 comprises a base 21 and a latch 23 extending from the base 21. Two supports 213 and a flange 218 are located on the base 21. Each of two fixing holes 2131 is defined in each of the two supports 213. The base 21 defines a first plane A, each support 213 defines an edge 2133, and an angle β defined between the edge 2133 and the first plane A is not less than about 30 degrees and not greater than about 60 degrees, to strengthen connection between each support 213 and the base 21. In an embodiment, the angle β is substantially equal to 45 degrees. The flange 218 and the two supports 213 are located on two opposite edges of the base 21. In another embodiment, the flange 218 defines a second plane B, the two supports 213 define a third plane C substantially parallel to the second plane B, and the second plane B and the third plane C are substantially perpendicular to the first plane A. The latch 23 defines a first cutout 231 in a first side and a second cutout 233 in a second side, and the first side is located between the second side and the base 21. In an embodiment, the mounting member 20 is made of a metal sheet plate.

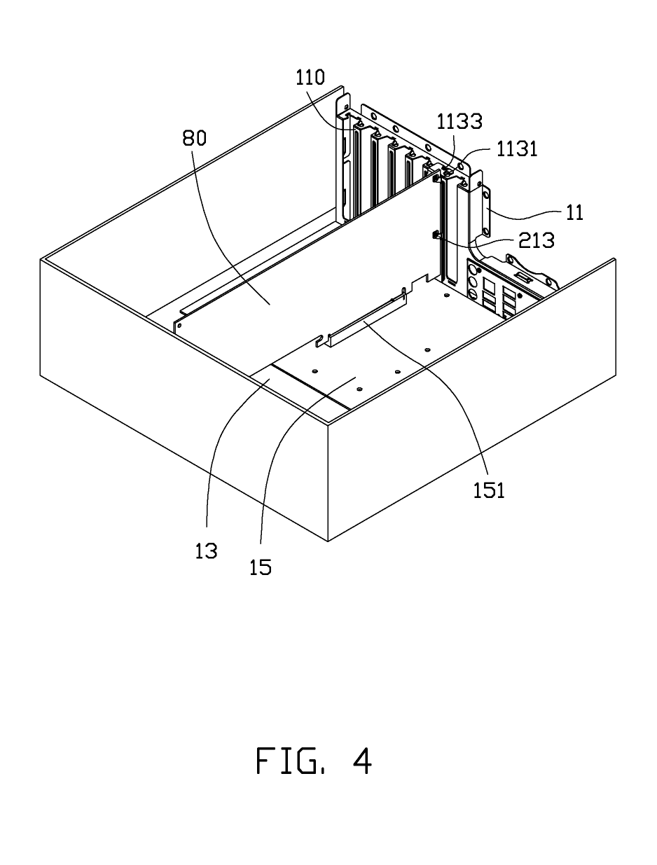

Referring also to FIG. 4, in assembly, an end of the card body 80 is placed between the flange 218 and the two supports 213. The two fixing holes 2131 of the two supports 213 are aligned with the two mounting holes 811 of the expansion card 70, and each of the two fasteners 30 is fixed into each of the two fixing holes 2131 and each of the two mounting holes 811 to secure the mounting member 20 to the card body 80. In an embodiment, the end of the card body 80 is touching the base 21 and sandwiched between the flange 218 and the two supports 213.

The expansion card 70 is placed into the chassis 10. The inserting portion 85 is inserted into the socket 151 of the motherboard 15. The mounting member 20 is attached to the card cage 110. The latch 23 is retained on the retaining portion 113. The first tab 1131 and the second tab 1133 are respectively engaged in the first cutout 231 and the second cutout 233. The base 21 abuts the positioning portion 111. The mounting member 20 covers one of the plurality of openings 1112. Therefore, the expansion card 70 is secured in the chassis 10.

When the computer system 100 is in use, vibration from the computer system 100 may be transmitted to the card body 80, so the two supports 213 may be vibrated relative to the base 21. The angle β defined between the edge 2133 and the first plane A of the base 21, which is not less than about 30 degrees and not greater than about 60 degrees, can prevent the vibration from damaging the connection between the two supports 213 and the base 21.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An expansion card comprising:
a card body; and
a mounting member comprising a base and a support extending from the base, the base fixed to the card body, the base defining a first plane facing the card body, the support defining an edge, the edge substantially extending from the base;
wherein an angle defined between the edge and the first plane is not less than about 30 degrees, but not more than about 60 degrees.

2. The expansion card of claim 1, wherein the angle is substantially equal to 45 degrees.

3. The expansion card of claim 1, wherein the mounting member further comprises a flange, the flange and the support are located on opposite sides of the base, and an end of the card body is sandwiched between the flange and the support.

4. The expansion card of claim 3, wherein the end of the card body touches the base.

5. The expansion card of claim 3, wherein the flange defines a second plane, the support defines a third plane substantially parallel to the second plane, and the second plane and the third plane are substantially perpendicular to the first plane.

6. The expansion card of claim 1, wherein the card body defines a mounting hole, the support defines a fixing hole, and the card body is fixed to the support with a fastener secured into the mounting hole and the fixing hole.

7. The expansion card of claim 1, wherein the mounting member further comprise a latch extending from the base, the latch defines a first cutout in a first side and a second cutout in a second side, and the first side is located between the second side and the base.

8. A computer system comprising:
a chassis comprising a bottom plate and a side plate located on the bottom plate, the side plate comprising a card cage;
a motherboard secured to the bottom plate; and
an expansion card comprising a card body and a mounting member secured to the card cage, the card body is secured and electronically coupled to the motherboard, the mounting member comprising a base and a support extending from the base, the base fixed to the card body, the base defining a first plane facing the card body, the support defining an edge, the edge substantially extending from the base;
wherein an angle defined between the edge and the first plane is not less than about 30 degrees and not more than about 60 degrees.

9. The computer system of claim 8, wherein the angle is substantially equal to 45 degrees.

10. The computer system of claim 8, wherein the mounting member further comprises a flange, the flange and the support are located on opposite sides of the base, and an end of the card body is sandwiched between the flange and the support.

11. The computer system of claim 10, wherein the end of the card body touches the base.

12. The computer system of claim 10, wherein the flange defines a second plane, the support defines a third plane substantially parallel to the second plane, and the second plane and the third plane are substantially perpendicular to the first plane.

13. The computer system of claim 8, wherein the card body defines a mounting hole, the support defines a fixing hole, and the card body is fixed to the support with a fastener secured into the mounting hole and the fixing hole.

14. The computer system of claim 8, wherein the mounting member further comprise a latch extending from the base, the latch defines a first cutout in a first side and a second cutout in a second side, and the first side is located between the second side and the base.

15. The computer system of claim 14, wherein the card cage comprises a tab, the tab is secured in either the first cutout or the second cutout.

16. The computer system of claim 8, wherein the motherboard comprises a socket, the card body comprises an inserting portion, the inserting portion is engaged in the socket to electronically couple the card body to the motherboard.
